(19) United States
(12) Patent Application Publication
(10) Pub. No.: US 2008/0197889 A1
(43) Pub. Date: Aug. 21, 2008

(54) Semiconductor Integrated Circuit Device and Mobile Device Using Same

(75) Inventors: Hirokazu Oki, Kyoto (JP); Yuzo Ide, Kyoto (JP)

Correspondence Address: FISH & RICHARDSON P.C., P.O. BOX 1022, MINNEAPOLIS, MN, 55440-1022, US

(73) Assignee: ROHM CO., LTD., Kyoto-shi (JP)

(21) Appl. No.: 11/597,031

(22) PCT Filed: May 18, 2005
(86) PCT No.: PCT/JP05/09035

§ 371 Date: Nov. 17, 2006

(30) Foreign Application Priority Data
May 20, 2004 (JP) 2004-149968

(51) Int. Cl. H03K 5/22; G11C 27/02; H03L 7/00

(52) U.S. Cl. 327/74; 327/77; 327/91

(57) ABSTRACT

An IC includes an internal circuit that switches between on-state and off-state in response to an external signal and also includes an oscillator circuit that is externally synchronized. The IC further includes a state holding circuit that, when pulses for synchronizing the oscillator circuit are inputted to a standby pulse input terminal, applies, to the internal and the oscillator circuits, as an operation signal, a voltage obtained by rectifying pulses outputted from a comparator, and, when a constant voltage for non-operation is applied to the standby pulse input terminal for a given time period, applies, to the internal and oscillator circuits, as a non-operation signal, a constant voltage outputted from the comparator.

### TECHNICAL FIELD

The present invention relates to a semiconductor integrated circuit device and a mobile device using this device. The invention more specifically relates to a semiconductor integrated circuit device provided with a standby function which, in order to reduce the standby power, switches by a standby signal externally given, between an ON state in which operation is performed and an OFF state in which the operation is stopped, and also which operates in accordance with a pulse signal externally provided. The invention also relates to a mobile device using the semiconductor integrated circuit device.

### BACKGROUND ART

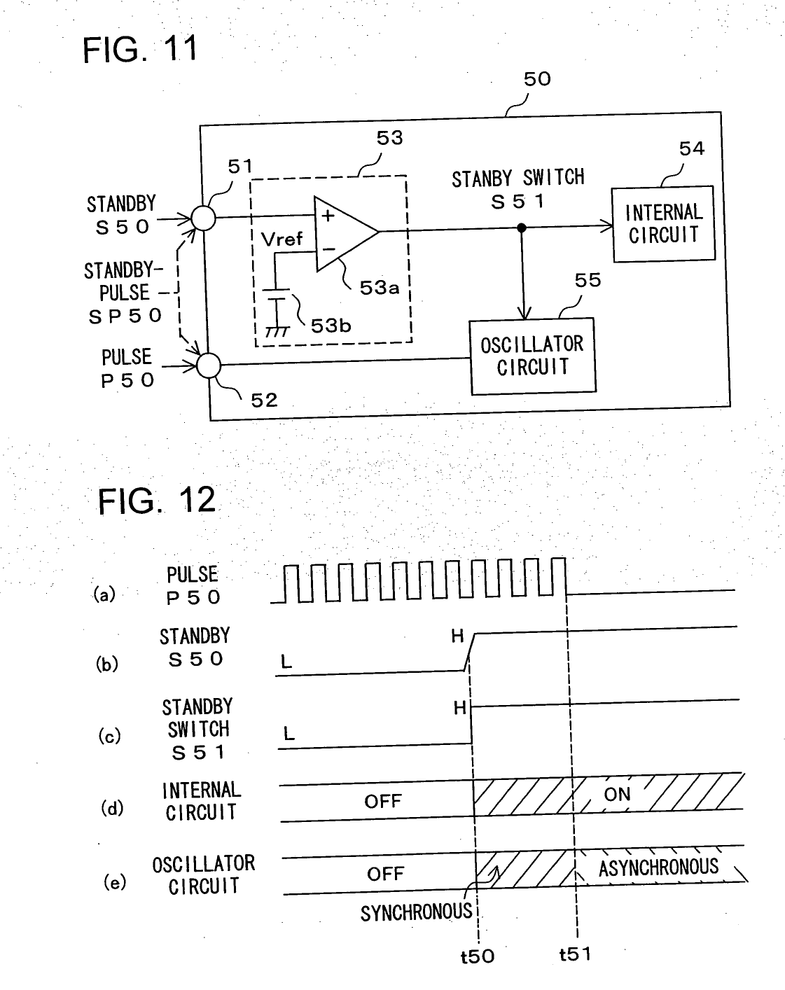

FIG. 11 is a block diagram schematically showing the configuration of a conventional semiconductor integrated circuit device. In FIG. 11, numeral 50 denotes a semiconductor integrated circuit device (hereinafter referred to as IC (Integrated Circuit)) having predetermined functions. The IC50 is provided with: a standby input terminal 51 to which an external standby signal S50 is inputted; a pulse input terminal 52 to which an external pulse signal P50 is inputted; a comparator circuit 53 which compares a voltage of the standby input terminal 51 and a reference voltage Vref; an internal circuit 54 which, based on a standby switch signal S51 as a comparison result output of the comparator circuit 53, switches between an ON state in which a predetermined action is performed and an OFF state in which the operation is stopped; and an oscillator circuit 55 which, based on the standby switch signal S51, similarly switches between an ON state and an OFF state and also which performs oscillating operation through self oscillation or in synchronization with the external pulse signal P50.

If the oscillator circuit 55 is used in a manner such as to make self oscillation without synchronizing with an external signal, the pulse input terminal 52 for inputting the pulse signal P50 did not have to be provided. However, if the oscillator circuit 55 is caused to synchronize with an external signal, the pulse input terminal 52 had to be provided, and, as described above, the pulse signal P50 had to be inputted separately.

The comparator circuit 53 is formed of a comparator 53a and a reference voltage source 53b which generates the reference voltage Vref. A non-inversed input terminal (+) of the comparator 53a is connected to the standby input terminal 51, and an inversed input terminal (−) thereof is connected to the reference voltage source 53b, and its output is given as the standby switch signal S51 to the internal circuit 54 and the oscillator circuit 55. This comparator 53a sets an output at a high level (H level) when the voltage of the standby input terminal 51 is larger than the reference voltage Vref (that is, when the standby signal S50 is at a H level), while the comparator 53a sets an output at a low level (L level) when the voltage is smaller than the reference voltage Vref (that is, when the standby signal S50 is at a L level).

FIGS. 12A to 12E are diagrams for describing the signals and operating states of the circuits of the IC50 described above. Of the figures, FIG. 12A shows a waveform of the pulse signal P50, FIG. 12B shows a waveform of the standby signal S50, FIG. 12C shows a waveform of the standby switch signal S51, FIG. 12D shows the operating state of the internal circuit 54, and FIG. 12E shows the operating state of the oscillator circuit 55.

Before a time t50, that is, when the standby signal S50 is at a L level and thus the standby switch signal S51 is also at a L level, the internal circuit 54 and the oscillator circuit 55 are in an OFF state (void area). Then, at the time t50, when the standby signal S50 turns to a H level and the standby switch signal S51 turns to a H level, the internal circuit 54 and the oscillator circuit 55 turn into an ON state (diagonal area). The power consumption of the IC50 when the internal circuit 54 and the oscillator circuit 55 are in an OFF state is smaller than the power consumption when the internal circuit 54 and the oscillator circuit 55 are in an ON state.

Now, during a period when the standby switch signal S51 is at a H level and a pulse train is inputted as the pulse signal P50, that is, a period between the time t50 and a time t51 (diagonal area with upward sloping in FIG. 12E), the oscillator circuit 55 performs oscillating operation in synchronization with a pulse cycle of the pulse signal P50, that is, in an externally synchronized manner. During a period when the standby switch signal S51 is at a H level and also when a constant voltage is inputted as the pulse signal P50, that is, at the time t51 and thereafter (diagonal area with downward sloping of FIG. 12E), the oscillator circuit 55 performs oscillating operation through self oscillation (asynchronously).

In this manner, the IC50 is provided with: a standby function of, during a standby period when the standby signal S50 is at a L level, turning into an OFF state to thereby reduce the power consumption; and an external synchronization function of performing oscillating operation in synchronization with the external pulse signal P50.

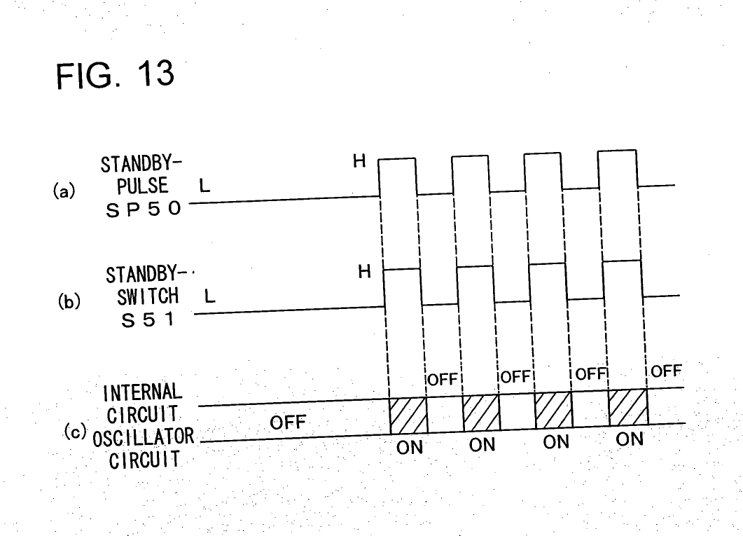

Such an IC50 does not perform a proper operation as shown in FIG. 13 when a pulse signal is inputted to the standby input terminal 51; thus, a pulse signal could not be inputted to the standby input terminal 51. Therefore, it was not possible that the standby signal S50 and the pulse signal P50 are used together and the standby input terminal 51 and the pulse input terminal 50 are used together to thereby provide them as one terminal.

FIGS. 13A to 13C are diagrams for describing operating states of the circuits of the IC50 when the standby-pulse signal SP50 is inputted to the standby input terminal 51 and the pulse input terminal 52 in the IC50 shown in FIG. 11. FIG. 13A shows a waveform of the standby-pulse signal SP50, FIG. 13B shows the waveform of the standby switch signal S51, and FIG. 13C shows the operating state of the internal circuit 54 and the oscillator circuit 55. Here, the standby-pulse signal SP50 is a signal having the standby signal S50 and the pulse signal P50 described above commonly shared. For example, when the standby signal S50 is at a L level, it is left at the L level, and to bring it into an operating state, the same pulse signal as that of the pulse signal P50 is inputted to the standby signal S50. This permits expressing the two signals in one signal. This standby-pulse signal SP50 as a common signal, as shown by a dotted line of FIG. 11, is inputted to the standby input terminal 51 and the pulse input terminal 52 of the IC50.

To bring the IC50 into a standby state, the standby-pulse signal SP50 is kept at a L level and thus the standby switch signal S51 is also kept at a L level; thus, each of the internal circuit 54 and the oscillator circuit 55 is in an OFF state (void area). However, to cause the IC50 to operate, the standby-pulse signal SP50 becomes a pulse signal of a predetermined cycle, and the standby switch signal S51 also becomes a pulse signal of the same period. In another word, internal circuit 54 and the oscillator circuit 55 each repeat an ON state (bias area) and an OFF state in the predetermined cycle. Such a state cannot be said to be a state in which the IC50 is operating properly.

Therefore, to cause the IC50 to operate properly in an externally synchronized manner, as described above, the standby signal S50 and the pulse signal P50 had to be respectively inputted to the standby input terminal 51 and the pulse input terminal 52 which are independently provided.

As one of methods of reducing the number of terminals by way of having terminals commonly shared, there is an integrated circuit chip (for example, see patent document 1) having a test mode terminal and a reset terminal commonly shared.
[Patent Document 1] Japanese Patent Application Laid-open No. H7-244124

### DISCLOSURE OF THE INVENTION

### Problems to be Solved by the Invention

Similarly, capability of having the standby input terminal 51 and the pulse input terminal 52 commonly shared to provide them as on terminal reduces the number of terminals of the IC50, which permits downsizing of the IC50.

However, a conventional technology described in patent document 1 is a technology having the test mode terminal for performing a functional test of a logical circuit and the reset terminal for resetting the logical circuit commonly shared, and this conventional technology is not applicable to the one having the standby input terminal and the pulse input terminal commonly shared to thereby provide them as one terminal.

Some of devices and the like which operate in response to an output from the IC50 properly operate in response to the output when the oscillator circuit 55 of the IC50 is performing oscillating operation in an externally synchronized manner. For example, assume that the IC50 is an IC for a switching regulator and a switching regulator apparatus using this IC50 drives a switching element by an output pulse signal from the IC50 and smoothes an obtained pulse voltage to thereby generate a stabilized output DC voltage.

When two of such a switching regulator apparatus is brought into parallel operation, to reduce the noise level of a switching noise, the two switching regulator devices had better be operated asynchronously with each other. This results in a larger frequency band of the switching noise than the frequency band when the switching regulator devices are individually operated, thus causing a risk that different device are affected by this switching noise. Therefore, from a viewpoint of reducing the frequency band of the switching noise, the switching timing of the both switching regulator devices may be matched by providing the same pulse signal to the ICs50 of the both switching regulator devices to operate the ICs50 in an externally synchronized manner. However, when the pulse signal provided to one of the ICs50 disappears for some reason, the switching cycles of the switching regulator devices disagree with each other, thus resulting in an increase in the frequency band of the switching noise as described above.

As described above, when the pulse signal is no longer inputted for an unexpected reason (wiring abnormality or the like), the IC50 turns into a externally-non-synchronized state, which possibly causes abnormal operation of a different device depending on the noise.

In view of the problem described above, it is an object of the present invention to provide a semiconductor integrated circuit device which can be downsized through reducing the number of terminals by having a standby input terminal and a pulse input terminal commonly shared, and also which, when a pulse signal for external synchronization is no longer inputted, can stop its operation to thereby prevent abnormal operation of a different device or the like. It is also an object of the invention to provide a mobile device using this semiconductor integrated circuit device.

### Means for Solving the Problem

To achieve the object described above, one aspect of the present invention provides a semiconductor integrated circuit device capable of stopping operation based on a signal externally given to a signal input terminal. The semiconductor integrated circuit device turns into an operation stopped state when the signal inputted to the signal input terminal is fixed at a first predetermined level and turns into an operating state when the signal is fixed at a second predetermined level or is a pulse signal of a predetermined cycle.

According to this configuration, this semiconductor integrated circuit device switches between the operation stopped state and the operating state based on a signal inputted to one signal input terminal, and also can maintain its operating state even if the inputted signal is a pulse signal.

According to another aspect of the invention, a semiconductor integrated circuit comprising an internal circuit and an oscillator circuit which, based on a signal externally given, switch between an ON state in which operation is performed and an OFF state in which the operation is stopped, the oscillator circuit operating in accordance with a pulse signal externally given. The semiconductor integrated circuit is so formed as to be provided with: a signal input terminal, a comparator circuit which compares a voltage of the signal input terminal and a reference voltage and then outputs a first and a second voltages, and a state holding circuit which holds the outputs of the comparator circuit and provides the outputs to the internal circuit and the oscillator circuit, wherein, when a pulse for synchronizing the oscillator circuit is inputted to the signal input terminal, the state holding circuit converts a pulse outputted from the comparator circuit into a DC voltage and gives the voltage as an operation signal to the internal circuit and the oscillator circuit, and when a constant voltage for non-operation is given to the signal input terminal for a predetermined period, gives as a non-operation signal a constant voltage outputted from the comparator circuit to the internal circuit and the oscillator circuit.

According to this configuration, when the constant voltage for non-operation is given to the signal input terminal for the predetermined period, the internal circuit and the oscillator circuit can be turned into an OFF state, and when the pulse for synchronizing the oscillator circuit is given to the signal input terminal, the internal circuit and the oscillator circuit can be turned into an ON state and also the oscillator circuit can be caused to oscillate in synchronization with this pulse.

For example, if the state holding circuit gives, as the non-operation signal, the constant voltage outputted from the comparator circuit to the internal circuit and the oscillator circuit when a signal is not inputted externally to the signal input terminal, the internal circuit and the oscillator circuit can be turned into an OFF state when a signal is not inputted externally to the signal input terminal.

For example, if the state holding circuit gives the DC-converted voltage as the operation signal to the internal circuit and the oscillator circuit for a fixed period since when the pulse for synchronizing the oscillator circuit is no longer inputted to the signal input terminal, the internal circuit and the oscillator circuit can be held in an ON state when the pulse is interrupted for only a short period, and the internal circuit and the oscillator circuit can be held in an OFF state when the pulse is interrupted for a long period.

For example, if the state holding circuit comprises a capacitor which is discharged or charged when the output of the comparator circuit becomes the first level voltage and which is discharged or charged when the output of the comparator circuit becomes the second level voltage and if a voltage of the capacitor is provided as the DC-converted voltage as the operation signal or the constant voltage for non-operation, the pulse outputted from the comparator circuit can be converted into a DC form and also the internal circuit and the oscillator circuit can be held in an ON state while charge is accumulated in the capacitor or until charge is accumulated in the capacitor.

For example, if the state holding circuit comprises: a first transistor which, when the output of the comparator circuit becomes the first level voltage, brings the capacitor into either one of a conducting state and a cut off state to discharge or charge the capacitor and, when the output of the comparator circuit becomes the second level voltage, brings the capacitor in said one state into another state to charge or discharge the capacitor; and a second transistor which is connected to an internal power source and which is conducted or cut-off by the voltage of the capacitor, and if a voltage from the second transistor is provided as the DC-converted voltage as the operation signal or the constant voltage for non-operation, the pulse outputted from the comparator circuit can be converted into a DC form and also the internal circuit and the oscillator circuit can be held in an ON state until the voltage of the capacitor increases or decreases to a predetermined voltage which have the second transistor conducted or cut off.

For example, if the transistors are MOS transistors, the power consumption of the state holding circuit can be reduced.

For example, if a constant current source or a resistance for determining values of currents charged into and discharged from the capacitor is provided, the holding period for which the internal circuit and the oscillator circuit are held in an ON state can be adjusted.

For example, if a resistance is provided which is connected between the signal input terminal and a power source or a ground inside the device, this can prevent a potential of the signal input terminal from becoming unstable when a signal is not inputted externally to the signal input terminal.

According to another aspect of the present invention, the semiconductor integrated circuit device is used in a mobile device. This permits achieving downsizing and weight saving of the mobile device, thus permitting even better mobility of the mobile device.

### Advantages of the Invention

According to the present invention, based on a signal inputted to one signal input terminal, an internal circuit and an oscillator circuit switch between an operation-stopped state and an operating state, and even when this inputted signal is a pulse signal, its operating state can be maintained. Therefore, instead of inputting a standby signal and a pulse signal for external synchronization respectively to two terminals, the standby signal and the pulse signal can be commonly shared to thereby provide them as one terminal, thereby reducing the number of terminals, which permits achieving a downsized and low-cost semiconductor integrated circuit device.

According to the invention, when a constant voltage for non-operation is given to the signal input terminal, the internal circuit and the oscillator circuit can be turned into an OFF state, and when a pulse for synchronizing the oscillator circuit is inputted to the signal input terminal, the internal circuit and the oscillator circuit can be turned into an ON state and also the oscillator circuit can be caused to oscillate in synchronization with this pulse. Therefore, providing only one signal input terminal permits achieving both a standby function of switching between an ON state and an OFF state and an external synchronization function. Consequently, two terminals for inputting the standby signal and the pulse signal for external synchronization, respectively, can be provided as one terminal, thus permitting downsizing and cost reduction of the semiconductor integrated circuit device.

When a signal is not inputted externally to the signal input terminal, the internal circuit and the oscillator circuit can be turned into an OFF state; thus, when a signal is no longer inputted to the signal input terminal due to abnormality or the like, the internal circuit and the oscillator circuit can be turned into an OFF state to stop operation, thereby preventing abnormal operation of a different device or the like.

The state holding circuit can hold the internal circuit and oscillator circuit in an ON state when the pulse for synchronizing the oscillator circuit inputted to the signal input terminal is interrupted for only a short period and can turn the internal circuit and oscillator circuit into an OFF state when the pulse is interrupted for a long period. This permits preventing operation from stopping due to noise applied to the signal input terminal or the like and also permits preventing abnormal operation of a different device or the like by stopping operation when a signal is no longer inputted to the signal input terminal.

According to the invention, a semiconductor integrated circuit device that can be downsized is used in a mobile device, thus permitting achieving a downsized and lighter-weight mobile device with even better mobility.

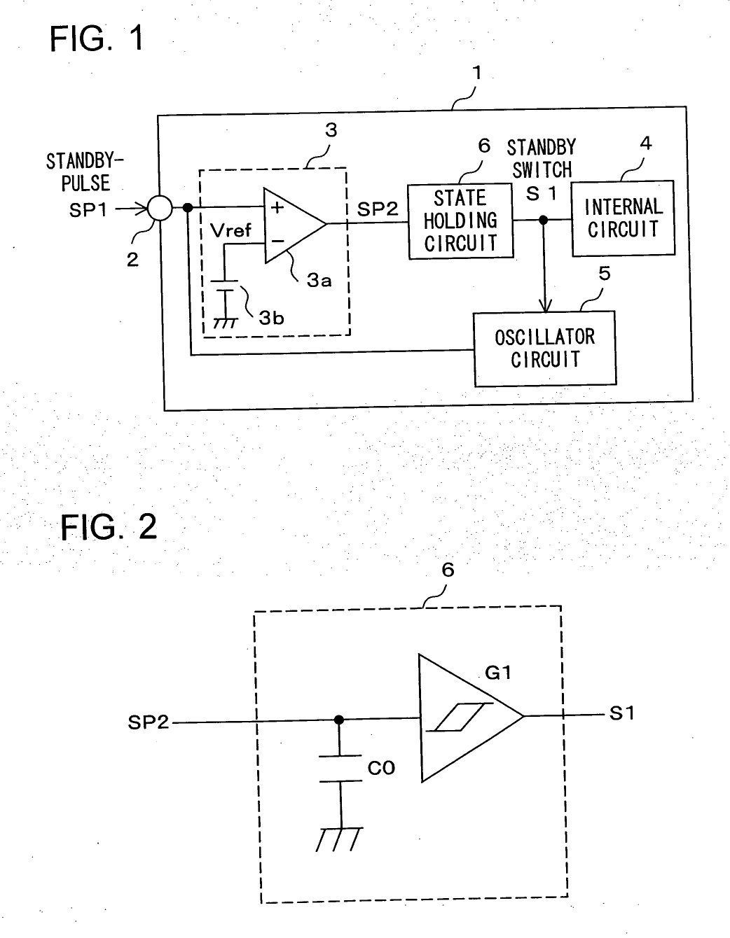

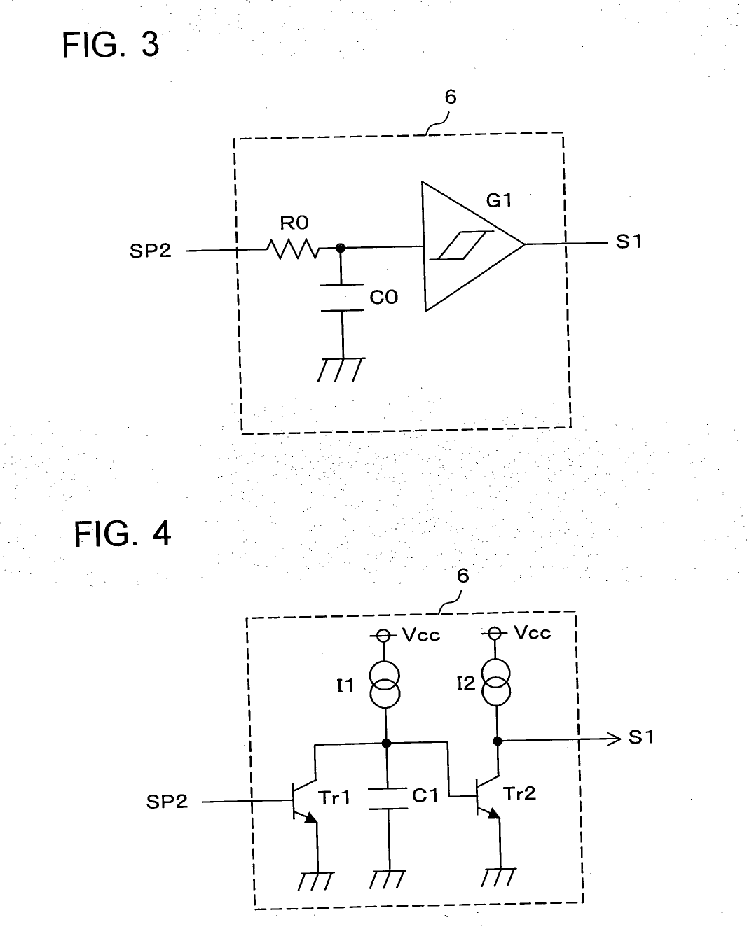

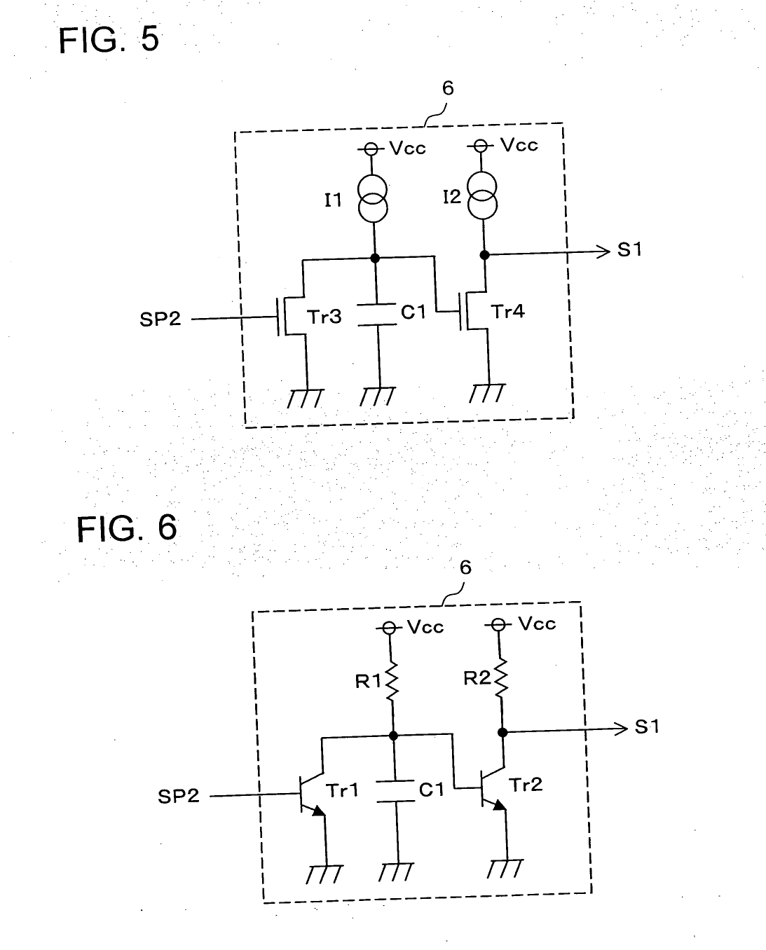

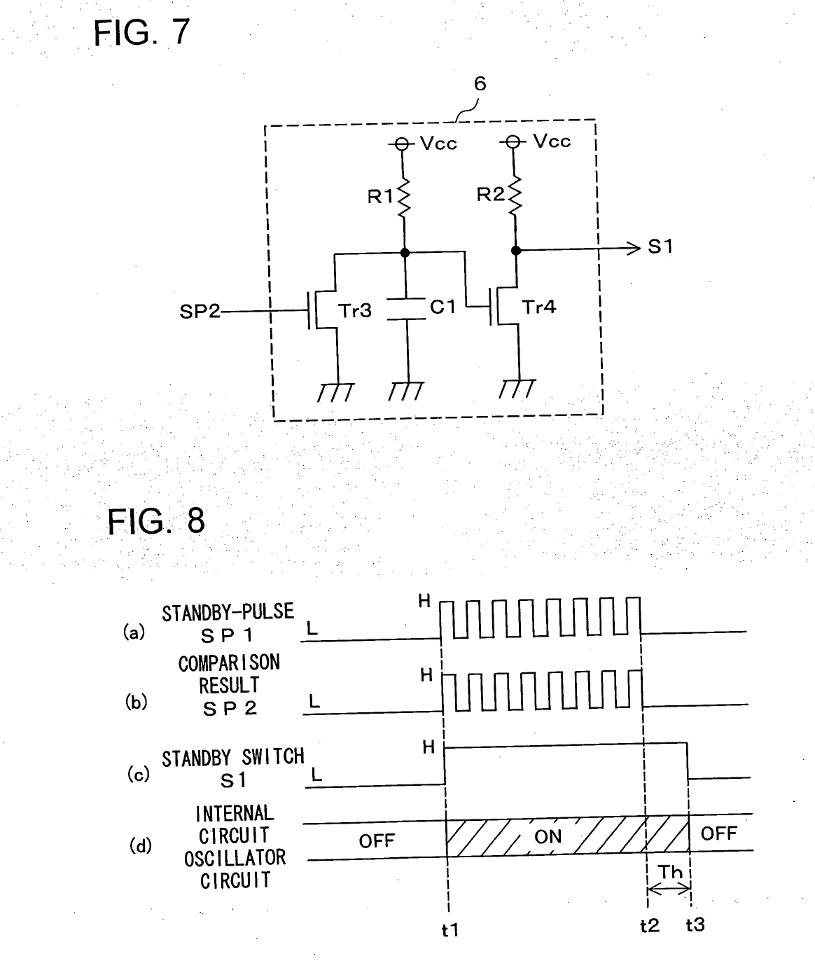

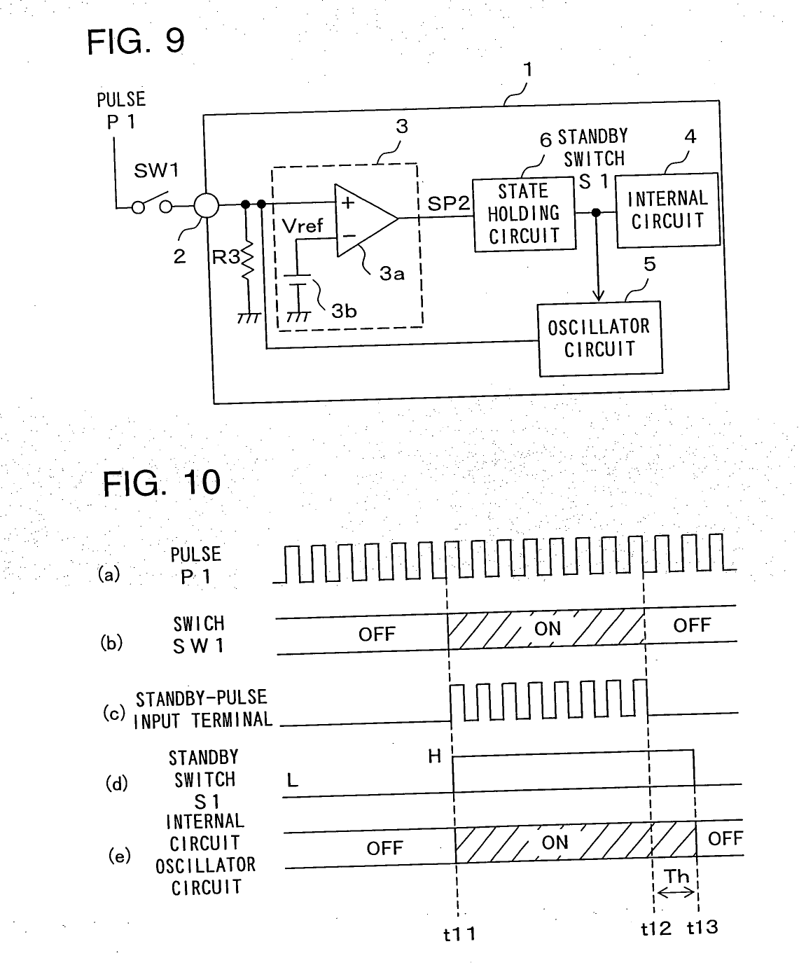

### BRIEF DESCRIPTION OF DRAWINGS

[FIG. 1] A block diagram showing the configuration of an IC (semiconductor integrated circuit device) according to a first embodiment of the present invention.

[FIG. 2] A circuit diagram showing a circuit example of a state holding circuit shown in FIG. 1.

[FIG. 3] A circuit diagram showing another circuit example of the state holding circuit shown in FIG. 1.

[FIG. 4] A circuit diagram showing another circuit example of a state holding circuit shown in FIG. 1.

[FIG. 5] A circuit diagram showing another circuit example of a state holding circuit shown in FIG. 1.

[FIG. 6] A circuit diagram showing another circuit example of a state holding circuit shown in FIG. 1.

[FIG. 7] A circuit diagram showing another circuit example of a state holding circuit shown in FIG. 1.

[FIG. 8] A diagram for explaining signals and operating states of circuits of the IC shown in FIG. 1.

[FIG. 9] A block diagram showing the configuration of an IC (semiconductor integrated circuit device) according to a second embodiment of the invention.

[FIG. 10] A diagram for explaining signals and operating states of circuits of the IC shown in FIG. 9.

[FIG. 11] A block diagram showing the configuration of a conventional IC.

[FIG. 12] A diagram for explaining signals and operating states of circuits of the IC shown in FIG. 11.

[FIG. 13] A diagram for explaining signals and operating states of circuits of the IC in another state shown in FIG. 11.

### LIST OF REFERENCE SYMBOLS

1 IC (semiconductor integrated circuit device)

2 Standby-pulse input terminal (signal input terminal)

3 Comparator circuit

3a Comparator

3b Reference voltage source

4 Internal circuit

5 Oscillator circuit

6 State holding circuit

C0, C1 Capacitor

I1, I2 Constant current source

R0, R1, R2, R3 Resistance

P1 Pulse signal

S1 Standby switch signal

SP1 Standby-pulse signal

SP2 Comparison result signal

Tr1, Tr2 NPN transistor

Tr3, Tr4 MOS transistor

Vcc Internal power source

### BEST MODE FOR CARRYING OUT THE INVENTION

Hereinafter, the embodiments of the present invention will be described with reference to the accompanying drawings. FIG. 1 is a block diagram schematically showing the configuration of an IC according to a first embodiment of the invention. In FIG. 1, numeral 1 denotes an IC (semiconductor integrated circuit device) having predetermined functions. The IC1 is provided with: a standby-pulse input terminal (signal input terminal) 2 to which an external standby-pulse signal SP1 is inputted; a comparator circuit 3 which compares a voltage of the standby-pulse input terminal 2 and a reference voltage Vref; a state holding circuit 6 which generates a standby switch signal S1 based on a comparison result signal SP2 as an output of the comparator circuit 3; an internal circuit 4 which, based on the standby switch signal S1, switches between an ON state in which predetermined operation is performed and an OFF state in which the operation is stopped; and an oscillator circuit 5 which, based on the standby switch signal S1, similarly switches between an ON state and an OFF state and also which is oscillatable in synchronization with the standby-pulse signal SP1.

Here, the standby-pulse signal SP1 is a signal for switching the IC1 between an ON state and an OFF state and also for causing the IC1 to perform synchronous operation in a predetermined cycle, and thus, as is the case with the standby-pulse signal SP50 described in the conventional example, is, for example, a signal which is kept at a L level to bring the IC1 into an OFF state and which is provided as a pulse signal of a predetermined cycle to cause the IC1 to perform synchronous operation.

The comparator circuit 3 is formed of a comparator 3a and a reference voltage source 3b which generates the reference voltage Vref. A non-inversed input terminal (+) of the comparator circuit 3 is connected to the standby-pulse input terminal 2, and an inversed input terminal (−) thereof is connected to the reference voltage source 3b, and its output is given as a signal SP2 to the state holding circuit 6. This comparator 3a sets an output at a high level (first level voltage) when the voltage of the standby-pulse input terminal 2 is larger than the reference voltage Vref (that is, when the standby-pulse signal SP1 is at a H level (second predetermined level), while the comparator 3a sets an output at a low level (second level voltage) when the voltage is smaller than the reference voltage Vref (that is, when the standby-pulse signal SP1 is at a L level (first predetermined level).

The state holding circuit 6 holds the standby switch signal S1 at a H level when the comparison result signal SP2 turns to a high level or at a H level for a predetermined period, and when a condition in which the comparison result signal SP2 is at a L level continues for over a predetermined holding period, releases the hold and brings the standby switch signal S1 to a L level. The state holding circuit 6 is, as in this embodiment, adapted to set the standby switch signal S1 at a L level when the standby-pulse signal SP1 is not inputted to the standby-pulse input terminal 2 (for example, when disconnection of external wiring or the like occurs). The state holding circuit 6 which perform such operation can be realized by a circuit using a capacitor C0 as shown in FIG. 2.

The capacitor C0 is charged when the comparison result signal SP2 turns to a high level and discharged when the comparison result signal SP2 turns to a low level. Then, a charge voltage of the capacitor C0 is inputted to a Schmitt trigger gate G1, and an output of the Schmitt trigger gate G1 is provided as the standby switch signal S1. This Schmitt trigger gate G1 is for shaping the standby switch signal S1 into a clear square wave. The standby switch signal S1 can be held at a H level by such a circuit with charge cumulated in the capacitor C0 while the charge voltage of the capacitor C0 is over the threshold level of the Schmitt trigger gate G1.

As shown in FIG. 3, further connecting a resistance R0 permits determining values of currents charged into and discharged from the capacitor C0. That is, charging and discharging is performed based on a time constant based on the resistance R0 and the capacitor C0, thus permitting adjustment of the holding period for which the standby switch signal S1 is held at a H level.

The state holding circuit 6 can also be realized by a circuit as shown in FIG. 4. The state holding circuit 6 shown in FIG. 4 is formed of: a capacitor C1, NPN transistors Tr1 and Tr2, constant current sources I1 and I2, and an internal power source Vcc. To the base of the NPN transistor Tr1, the comparison result signal SP2 is to be given. The emitter of the NPN transistor Tr1 is connected to a ground. The collector of the NPN transistor Tr1 is connected to the internal power source Vcc via the constant current source I1, also connected to the ground via the capacitor C1, and further connected to the base of the NPN transistor Tr2. The emitter of the NPN transistor Tr2 is connected to the ground, and the collector thereof is connected to the internal power source Vcc via the constant current source I2. The collector voltage of the NPN transistor Tr2 is outputted as the standby switch signal S1.

In the state holding circuit 6 shown in FIG. 4 with such configuration, when the comparison result signal SP2 is at a H level, the NPN transistor Tr1 is turned on, the capacitor C1 is discharged via the NPN transistor Tr1, and the NPN transistor Tr2 is turned off, so that the standby switch signal S1 turns to a H level. Note that a resistance for limiting a current discharged from the capacitor C1 may be inserted in a discharge path thereof so that it takes much time for the standby switch signal S1 to turn to a H level.

On the other hand, when the comparison result signal SP2 is at a L level, the NPN transistor Tr1 is turned off, the capacitor C1 is charged with a constant current from the constant current source I1, and the voltage of the capacitor C1 gradually increases. Then, when the voltage of the capacitor C1 becomes higher than a predetermined voltage, the NPN transistor Tr2 is turned on, so that the standby switch signal S1 turns to a L level. At this point, during the period before the voltage of the capacitor C1 exceeds the predetermined voltage, the standby switch signal S1 is at a H level, and when the comparison result signal SP2 turns to a H level during this period, the standby switch signal is maintained at a H level.

In this manner, when the comparison result signal SP2 is at a H level for a predetermined period or longer or if it is a pulse signal of a predetermined cycle, the standby switch signal S1 is held at a H level. If the comparison result signal SP2 remains at a L level for a predetermined holding period or longer, the hold is released thereby bringing the standby switch signal S1 to a L level.

As shown in FIG. 5, it is possible to provide the state holding circuit 6 by using N-channel MOS transistors Tr3 and Tr4 instead of the NPN transistors Tr1 and 2 shown in FIG. 4. The use of MOS transistors achieves low power consumption. Also in this case, a resistance for limiting a current discharged from a capacitor C1 may be inserted in a discharge path thereof so that it takes much time for the standby switch signal S1 to turn to a H level.

Moreover, as shown in FIG. 6, it is possible to provide the state holding circuit 6 having the constant current sources I1 and I2 shown in FIG. 4 replaced with resistances R1 and R2, respectively. This permits simplified circuit configuration.

As shown in FIG. 7, it is possible to provide the state holding circuit 6 using N-channel MOS transistors Tr3 and Tr4 instead of the NPN transistors Tr1 and Tr2 shown in FIG. 6. This permits simplified circuit configuration, and the use of MOS transistors results in low power consumption.

The circuits shown in FIGS. 4 to 7 as detailed circuits of the state holding circuit 6 can have circuit configuration provided by having the NPN transistors replaced with PNP transistors or the N-channel MOS transistors replaced with P-channel MOS transistors and then reversing the polarity of the power sources.

FIGS. 8A to 8D are diagrams for describing signals and operating states of the circuits of the IC1 shown in FIG. 1. Of these figures, FIG. 8A shows a waveform of the standby-pulse signal SP1, FIG. 8B shows a waveform of the comparison result signal SP2, FIG. 8C shows a waveform of the standby switch signal S1, and FIG. 8D shows the operating state of the internal circuit 4 and the oscillator circuit 5. The pulse periods, pulse widths, and the like of the signals in the figures are drawn larger so as to be viewed easily, and thus they are different from actual pulse periods, pulse widths, and the like.

In FIGS. 8A to 8B, until a time ti, the standby-pulse signal SP1 remains at a L level and the IC1 is in an OFF state. At this point, the comparison result signal SP2 also remains at a L level, and thus the standby-pulse signal SP1 as an output of the state holding circuit 6 is at a L level and the internal circuit 4 and the oscillator circuit 5 are each in an OFF state (void area).

Then, from the time t1, to bring the IC1 into an ON state, the standby-pulse signal SP1 changes to a pulse signal of a predetermined cycle. At this point, the comparison result signal SP2 also turns to a pulse signal of the predetermined cycle, and when the comparison result signal SP2 change from a L level to a H level at the time t1, the standby switch signal S1 as the output of the state holding circuit 6 turns to a H level and thereafter is held at a H level while pulses are inputted in the predetermined cycle. Therefore, the internal circuit 4 and the oscillator circuit 5 each turn into an ON state (diagonal area). At this point, the oscillator circuit 5 performs oscillating operation in synchronization with the pulse cycle of the standby-pulse signal SP1.

Then, when, from a time t2, the standby-pulse signal SP1 remains at a L level and the comparison result signal SP2 remains at a L level so as to bring the IC1 into an OFF state again, the state holding circuit 6 releases the hold after passage of a predetermined holding period Th, i.e., at a time t3, so as to bring the standby switch signal S1 to a L level. Therefore, at the time t3 and thereafter, the internal circuit 4 and the oscillator circuit 5 are each in an OFF state (void area).

In this manner, by providing the state holding circuit 6 and holding the standby switch signal S1 at a H level between the times t0 and t3, the internal circuit 4 and the oscillator circuit 5 can operate properly without repeating an ON state and an OFF state even when the standby-pulse signal SP1 has a pulse waveform.

In this manner, even with only one standby-pulse input terminal 2, the operating state of the IC1 can be switched properly between an ON state and an OFF state, and also the IC1 can be operated in an externally synchronized manner. Therefore, it is possible to have the standby input terminal and the pulse input terminal commonly shared to provide these terminals as one terminal to thereby reduce the number of terminals. This therefor permits adopting a small-size package as a package for the IC1, thus achieving downsizing and cost reduction of the IC1.

Moreover, even when the standby-pulse signal SP1 is not inputted due to abnormality on the transmission side, disconnection of the wiring route, or the like, as is the case where the operation of the IC1 is stopped, the standby switch signal S1 turns to a L level and the internal circuit 4 and the oscillator circuit 5 each turn into an OFF state after the holding period Th. This therefore prevents the IC1, which is supposed to be operating in an externally synchronized manner, from operating not in an externally synchronized manner without noticing and thus causing abnormal operation of a different device or the like.

Moreover, the holding period Th can be adapted to be set by the state holding circuit 6. This period may be set at approximately a period corresponding to several pulses of the standby-pulse signal SP1 for the following reason. If the holding period Th is short, even when the waveform of the standby-pulse signal SP1 becomes abnormal in accordance with this short period due to noise or the like, the standby switch signal S1 may change to a L level during this period whereby the operation of the IC1 may stop. If the holding period Th is long, a condition where the internal circuit 4 operates and the oscillator circuit 5, due to absence of pulses, is actually not in operation or not in an externally synchronized state continues for a long period, thereby resulting in a risk that a different device using an output of the IC1 is caused to operate abnormally.

FIG. 9 is a block diagram schematically showing the configuration of an IC according to a second embodiment of the invention. In FIG. 9, the same portions as those of FIG. 1 are provided with the same numerals and thus omitted from the description. The IC1 shown in FIG. 9 is different from the IC1 shown in FIG. 1 in that a resistance R3 is provided between the standby-pulse input terminal 2 and the ground. The resistance R3, instead of the ground, may be connected to the internal power source and the logic of the signals may be reversed. In addition, to the standby-pulse input terminal 2, a pulse signal P1 is inputted externally via a switch SW1. The pulse signal P1 is a pulse signal of a predetermined cycle for bringing the oscillator circuit 5 of the IC1 to be externally synchronized, and the switch SW1 is a switch for switching the operating state of the IC1 between an ON state and an OFF state.

The operation of the IC1 with such configuration shown in FIG. 9 will be described with reference to FIGS. 10A to 10E. FIGS. 10A to 10E are diagrams for describing the signals and operating states of the circuits of the IC1 described above when such configuration is adopted. FIG. 10A shows a waveform of the pulse signal P1, FIG. 10B shows ON/OFF states of the switch SW1, FIG. 10C shows a voltage waveform of the standby-pulse input terminal 2, FIG. 10D shows a waveform of the standby switch signal S1, and FIG. 10E shows the operating state of the internal circuit 4 and the oscillator circuit 5. The pulse cycles, pulse widths, and the like of the signals shown in the figures are drawn larger so as to be viewed easily, and thus they are different from actual pulse cycles, pulse widths, and the like.

In FIGS. 10A to 10E, until a time t11, the switch SW1 is off (open), and the IC1 is in an OFF state. At this point, the potential of the standby-pulse input terminal 2 is a ground potential due to the presence of the resistance R3. The resistance R3 is, as described above, a resistance for preventing the standby-pulse input terminal 2 from opening and then becoming unstable when the switch SW1 is off. Moreover, since the voltage of the standby-pulse input terminal 2 turns to a L level and the comparison result signal SP2 also turns to a L level, the standby switch signal S1 as an output of the state holding circuit 6 turns to a L level and the internal circuit 4 and the oscillator circuit 5 each are in an OFF state (void area).

Then, when from a time t11, the switch SW1 is turned on (closed) and the pulse signal P1 is inputted to the standby-pulse input terminal 2 so as to turn the IC1 into an ON state, the comparison result signal SP2 becomes a pulse signal of the same cycle as that of the pulse signal P1, and thus the standby switch signal S1 as the output of the state holding circuit 6 turns to a H level and thereafter is held at a H level in a predetermined cycle while pulses are inputted. Therefore, the internal circuit 4 and the oscillator circuit 5 each turn into an ON state (diagonal area). At this point, the oscillator circuit 5 performs oscillating operation in synchronization with the pulse cycle of the pulse signal P1.

Then, when, from a time t12, the switch SW1 is turned off and the pulse signal P1 is no longer inputted to the standby-pulse input terminal 2 so as to turn the IC1 into an OFF state again, the comparison result signal SP2 remains at a L level, and thus the state holding circuit 6 releases the hold after passage of a predetermined holding period Th, i.e., at a time t13, to thereby bring the standby switch signal S1 to a L level. Therefore, at the time t13 and thereafter, the internal circuit 4 and the oscillator circuit 5 are each in an OFF state (void area).

As described above, by switching, via the external switch SW1, between inputting and not inputting the pulse signal P1 to the standby-pulse input terminal 2, the ON state and OFF state of the internal circuit 4 and the oscillator circuit 5 can be switched properly, and also the oscillator circuit 5 can be operated in an externally synchronized manner.

Moreover, an embodiment can be provided with reversed logic of the logic of all the signals in the embodiments described above. In addition, pulse signals as the standby-pulse signal SP1 and the pulse signal P1 may be AC signals.

Moreover, the use of the IC1 described above for a mobile device permits downsizing and weight saving of the mobile device, thus achieving the mobile device with even better mobility.

The invention is not limited to the embodiment described above, and thus modification can be added as appropriate to the configuration or the like of each part within the scope not departing from the sprites of the invention.

### INDUSTRIAL APPLICABILITY

The present invention is a technology which is useful for downsizing a semiconductor integrated circuit device and a mobile device using this device and also improving the reliability. The invention is applicable for use in, for example, a switching power supply device which is operated in parallel.

1. A semiconductor integrated circuit device capable of stopping operation based on a signal externally given to a signal input terminal, the semiconductor integrated circuit device turning into an operation stopped state when the signal inputted to the signal input terminal is fixed at a first predetermined level and turning into an operating state when the signal is fixed at a second predetermined level or is a pulse signal of a predetermined cycle.

2. A semiconductor integrated circuit comprising an internal circuit and an oscillator circuit which, based on a signal externally given, switch between an ON state in which operation is performed and an OFF state in which the operation is stopped, the oscillator circuit operating in accordance with a pulse signal externally given, the semiconductor integrated circuit being so formed as to be provided with:
a signal input terminal,
a comparator circuit which compares a voltage of the signal input terminal and a reference voltage and then outputs a first and a second voltages, and
a state holding circuit which holds the outputs of the comparator circuit and provides the outputs to the internal circuit and the oscillator circuit,
wherein, when a pulse for synchronizing the oscillator circuit is inputted to the signal input terminal, the state holding circuit converts a pulse outputted from the comparator circuit into a DC voltage and gives the voltage as an operation signal to the internal circuit and the oscillator circuit, and when a constant voltage for non-operation is given to the signal input terminal for a predetermined period, gives as a non-operation signal a constant voltage outputted from the comparator circuit to the internal circuit and the oscillator circuit.

3. The semiconductor integrated circuit device according to claim 2, wherein when a signal is not inputted externally to the signal input terminal, the state holding circuit gives, as the non-operation signal, the constant voltage outputted from the comparator circuit to the internal circuit and the oscillator circuit.

4. The semiconductor integrated circuit device according to claim 2, wherein, for a fixed period since when the pulse for synchronizing the oscillator circuit is no longer inputted to the signal input terminal, the state holding circuit gives the DC-converted voltage as the operation signal to the internal circuit and the oscillator circuit.

5. The semiconductor integrated circuit device according to claim 2,
wherein the state holding circuit comprises a capacitor which is or charged discharged when the output of the comparator circuit becomes the first level voltage and which is discharged or charged when the output of the comparator circuit becomes the second level voltage, and
wherein a voltage of the capacitor is provided as the DC-converted voltage as the operation signal or the constant voltage for non-operation.

6. The semiconductor integrated circuit device according to claim 5, comprising a constant current source or a resistance for determining values of currents charged into and discharged from the capacitor.

7. The semiconductor integrated circuit device according to claim 2,
wherein the state holding circuit comprises: a first transistor which, when the output of the comparator circuit becomes the first level voltage, brings the capacitor into either one of a conducting state and a cut off state to discharge or charge the capacitor, and when the output of the comparator circuit becomes the second level voltage, brings the capacitor in said one state into another state to charge or discharge the capacitor; and a second transistor which is connected to an internal power source and which is conducted or cut-off by the voltage of the capacitor, and
wherein a voltage from the second transistor is provided as the DC-converted voltage as the operation signal or the constant voltage for non-operation.

8. The semiconductor integrated circuit device according to claim 7, wherein the first and second transistors are MOS transistors.

9. The semiconductor integrated circuit device according to claim 7, comprising a constant current source or a resistance for determining values of currents charged into and discharged from the capacitor.

10. The semiconductor integrated circuit device according to claim 2, comprising a resistance connected between the signal input terminal and a power source or a ground inside the device.

11. A semiconductor integrated circuit device comprising:
a signal input terminal to which a control signal is inputted, the control signal forming a constant voltage waveform of a first level voltage to give an instruction for operation stop and forming a pulse waveform alternately repeating the first voltage level and a second voltage level in a predetermined cycle to give an instruction for operation permission;
a state holding circuit which, when the control signal is maintained at the first voltage level, generates an output signal of logic indicating operation stop, and, on the other hand, when the control signal is at the second voltage level or when the control signal is maintained at the second voltage level over a predetermined period, until the control signal is thereafter maintained at the first voltage level again over a predetermined period, generates an output signal of logic indicating operation permission;
an internal circuit whose operation acceptance and rejection are controlled based on an output logic of the state holding circuit; and
an oscillator circuit whose oscillation acceptance and rejection are controlled based on the output logic of the state holding circuit upon oscillating operation in synchronization with the pulse waveform of the control signal.

12. The semiconductor integrated circuit device according to claim 11, which is so formed as to have a comparator circuit for generating a comparison output signal of logic in accordance with a level difference between the voltage level of the control signal and a reference voltage,
wherein the state holding circuit generates an own output signal based on the comparison output signal.

13. The semiconductor integrated circuit device according to claim 11,
wherein the state holding circuit is so formed as to have a capacitor which is charged or discharged when the control signal is at the first voltage level and which is discharged or charged when the control signal is at the second voltage level, and
wherein a charge voltage of the capacitor is provided as the output signal.

14. The semiconductor integrated circuit device according to claim 13, wherein the state holding circuit is so formed as to have a constant current source or a resistance for determining values of currents charged into and discharged from the capacitor.

15. The semiconductor integrated circuit device according to claim 11, wherein the state holding circuit is so formed as to have: a first transistor which is closed or open when the control signal is at the first voltage level and which is open or closed when the control signal is at the second voltage level; a capacitor which is discharged when the first transistor is closed and charged when the first transistor is open; and a second transistor whose opening and closing is controlled in accordance with a charge voltage of the capacitor.

16. The semiconductor integrated circuit device according to claim 15, wherein the first and second transistors are MOS transistors.

17. The semiconductor integrated circuit device according to claim 15, wherein the state holding circuit is so formed as to have a constant current source or a resistance for determining values of currents charged into and discharged from the capacitor.

18. The semiconductor integrated circuit device according to claim 11, which is so formed as to have a resistance connected between the signal input terminal and a power source or a ground inside the device.

19. A mobile device having a semiconductor integrated circuit device comprising:
a signal input terminal to which a control signal is inputted, the control signal forming a constant voltage waveform of a first level voltage to give an instruction for operation stop and forming a pulse waveform alternately repeating the first voltage level and a second voltage level in a predetermined cycle to give an instruction for operation permission;
a state holding circuit which, when the control signal is maintained at the first voltage level, generates an output signal of logic indicating operation stop, and, on the other hand, when the control signal is at the second voltage level or when the control signal is maintained at the second voltage level over a predetermined period, until the control signal is thereafter maintained at the first voltage level again over a predetermined period, generates an output signal of logic indicating operation permission;
an internal circuit whose operation acceptance and rejection are controlled based on an output logic of the state holding circuit; and
an oscillator circuit whose oscillation acceptance and rejection are controlled based on the output logic of the state holding circuit upon oscillating operation in synchronization with the pulse waveform of the control signal.
